(19) United States
(12) Patent Application Publication
(10) Pub. No.: US 2024/0049418 A1
(43) Pub. Date: Feb. 8, 2024

(54) CHASSIS

(71) Applicant: PEGATRON CORPORATION, Taipei City (TW)

(72) Inventor: Po-Han Chen, Taipei City (TW)

(73) Assignee: PEGATRON CORPORATION, Taipei City (TW)

(21) Appl. No.: 18/324,772

(22) Filed: May 26, 2023

(30) Foreign Application Priority Data
Aug. 3, 2022 (TW) 111129159

(51) Int. Cl. H05K 7/14

(52) U.S. Cl. CPC H05K 7/1489

(57) ABSTRACT

A chassis includes a housing, a first bearing seat, a second bearing seat, and a connecting partition plate. The housing has an accommodating space. The first bearing seat is movably disposed in the accommodating space. The second bearing seat is movably disposed in the accommodating space and is adjacent to the first bearing seat. The connecting partition plate is disposed between the first bearing seat and the second bearing seat to fixedly connect the first bearing seat and the second bearing seat. The first bearing seat and the second bearing seat are adapted to synchronously move relative to the housing to be accommodated in the accommodating space or extend outside the accommodating space.

### CROSS-REFERENCE TO RELATED APPLICATION

This application claims the priority benefit of Taiwan application serial no. 111129159, filed on Aug. 3, 2022. The entirety of the above-mentioned patent application is hereby incorporated by reference herein and made a part of this specification.

### BACKGROUND

### Technical Field

The disclosure relates to a server chassis, and more particularly to a chassis with multiple nodes.

### Description of Related Art

In recent years, with the development of cloud services, the traditional servers are no longer able to meet various computing demands. As a result, a server with multi-node chassis has been developed recently. That is, the chassis is equipped with different types of computing elements such as central processing unit (CPU) and graphics processing unit (GPU). Therefore, the new server can meet different computing processing requirements and has scalability and variety.

The existing multi-node chassis requires the coexistence of the central processing unit and the graphics processing unit. The central processing unit and the graphics processing unit are usually connected through a cable. To avoid damage caused by the cables pulling against each other, when the server is performing maintenance or updating parts, it is necessary to simultaneously pull out the two nodes that install the central processing unit and the graphics processing unit.

Since the two nodes of the server are independent structures, it is necessary to use both hands when pulling them out, which causes inconvenience in operation.

### SUMMARY

The disclosure provides a chassis for a server that has multiple bearing seats and is adapted for installing multiple computing elements. The bearing seats are connected as one for moving synchronously.

The chassis of the disclosure includes a housing, a first bearing seat, a second bearing seat, and a connecting partition plate. The housing has an accommodating space. The first bearing seat is movably disposed in the accommodating space. The second bearing seat is movably disposed in the accommodating space and is adjacent to the first bearing seat. The connecting partition plate is disposed between the first bearing seat and the second bearing seat to fixedly connect the first bearing seat and the second bearing seat. The first bearing seat and the second bearing seat are adapted to synchronously move relative to the housing to be accommodated in the accommodating space or extend outside the accommodating space.

In an embodiment of the disclosure, the connecting partition plate has a connecting plate, multiple engaging pillars, and multiple screwing members. The connecting plate is located between the first bearing seat and the second bearing seat. The engaging pillars are disposed on a lateral surface of the connecting plate and engaged to the second bearing seat. The screwing members pass through the first bearing seat and the connecting plate and are screwed to a corresponding engaging pillar.

In an embodiment of the disclosure, the first bearing seat has a first hole, the second bearing seat has a second hole, and the first hole is adjacent to the second hole.

In an embodiment of the disclosure, multiple dissipation plates respectively disposed on bottom surfaces of the first bearing seat and the second bearing seat and closely attached to an opening of the housing are further included.

In an embodiment of the disclosure, multiple pull rings respectively disposed on outer edges of the first bearing seat and the second bearing seat and extending outside the housing are further included.

In an embodiment of the disclosure, a limiting stand fixedly disposed in the housing and having two sliding slots in which the first bearing seat and the second bearing seat are respectively disposed is further included. The first bearing seat and the second bearing seat are adapted to move linearly along the two sliding slots.

The chassis of the disclosure includes a housing, a first bearing seat, a second bearing seat, and a limiting stand. The housing has an accommodating space. The first bearing seat is movably disposed in the accommodating space. The second bearing seat is movably disposed in the accommodating space and is connected to the first bearing seat. The limiting stand is fixedly disposed in the housing and has two sliding slots in which the first bearing seat and the second bearing seat are respectively disposed. The first bearing seat and the second bearing seat are adapted to move linearly along the two sliding slots to be accommodated in the accommodating space or extend outside the accommodating space.

In an embodiment of the disclosure, the limiting stand has a guiding hole connecting the two sliding slots.

In an embodiment of the disclosure, a first calculation module and a second calculation module respectively disposed in the first bearing seat and the second bearing seat are further included.

In an embodiment of the disclosure, a cable passing through the first bearing seat and the second bearing seat through the guiding hole and respectively coupled to the first calculation module and the second calculation module is further included.

In an embodiment of the disclosure, the chassis has two screwing plates disposed on opposite sides of the chassis.

Based on the above, the chassis of the disclosure has a first bearing seat and a second bearing seat, which are adapted for installing multiple computing processing elements. The computing elements are connected to each other through cables. The first bearing seat and the second bearing seat are connected as one through the connecting partition plate, so that the user may pull out the first bearing seat and the second bearing seat from the housing synchronously to facilitate maintenance, repair, or update of the part. The chassis of the disclosure may avoid damage caused by cables pulling against each other when pulling them out as the first bearing seat and the second bearing seat move synchronously.

### BRIEF DESCRIPTION OF THE DRAWINGS

FIG. 1A is a perspective schematic view of a chassis in a storage state according to an embodiment of the disclosure.

FIG. 1B is a perspective schematic view of the chassis in FIG. 1A in a pulling state.

FIG. 1C is an exploded schematic view of components of the chassis in FIG. 1A.

FIG. 1D is a partial cross-sectional schematic view of the chassis in FIG. 1A along line A-A.

FIG. 2A is a perspective schematic view of a chassis using a limiting stand according another embodiment of the disclosure.

FIG. 2B is a perspective schematic view of the limiting stand and part of the housing in FIG. 2A.

### DESCRIPTION OF THE EMBODIMENTS

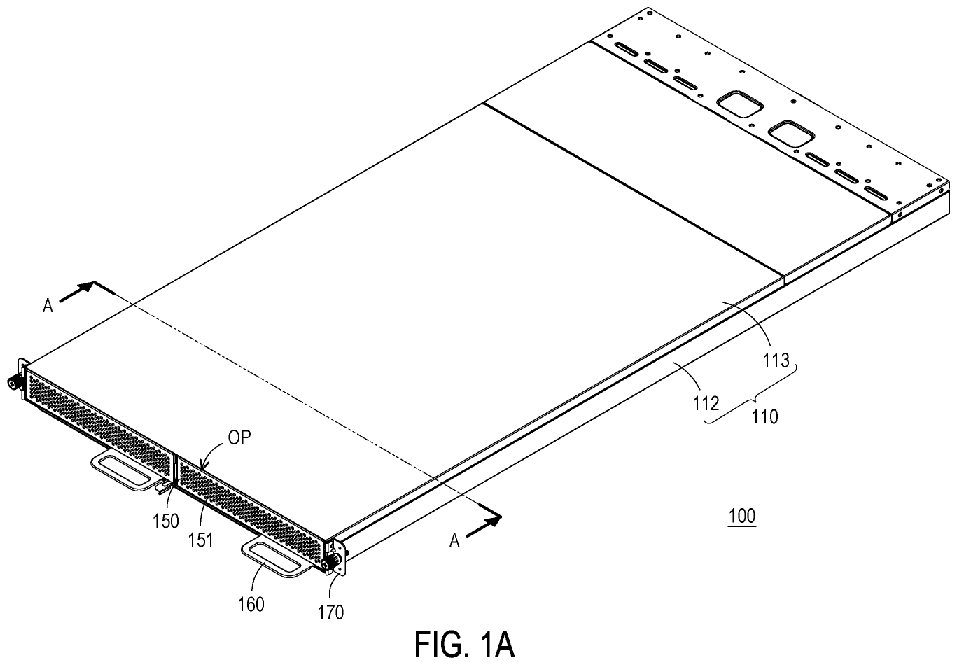

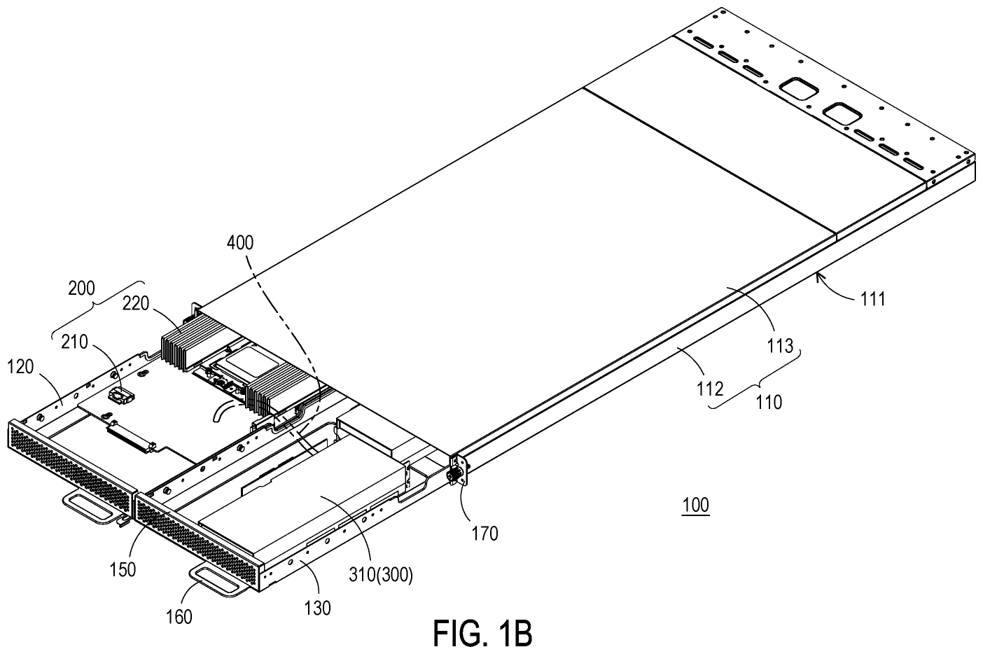

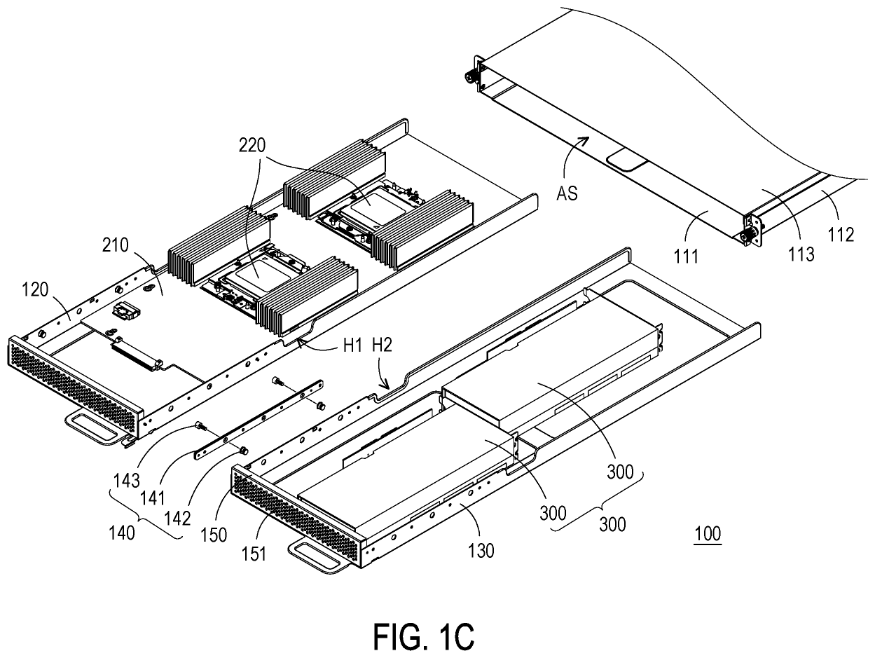

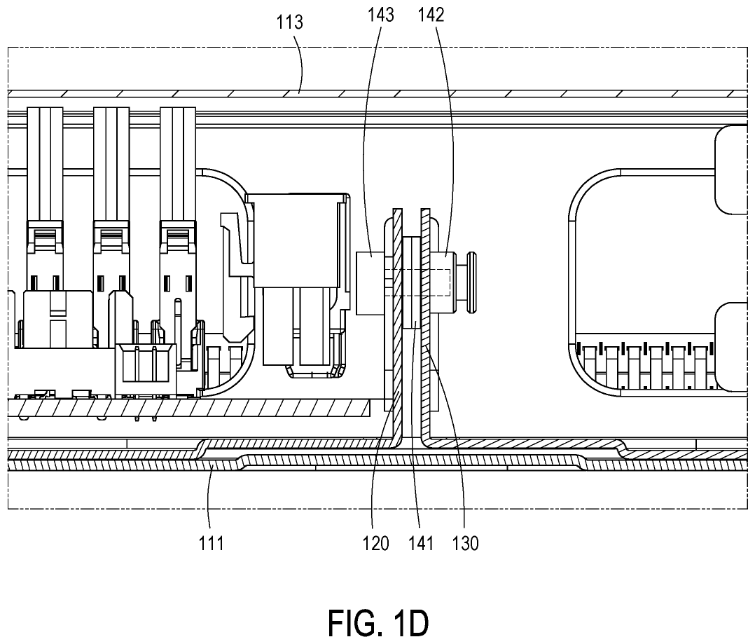

FIG. 1A is a perspective schematic view of a chassis in a storage state according to an embodiment of the disclosure. FIG. 1B is a perspective schematic view of the chassis in FIG. 1A in a pulling state. FIG. 1C is an exploded schematic view of components of the chassis in FIG. 1A. FIG. 1D is a partial cross-sectional schematic view of the chassis in FIG. 1A along line A-A.

Referring to FIG. 1A and FIG. 1B, a chassis 100 of the disclosure adopts a multi-node architecture, and multiple calculation modules may be installed at the same time to achieve the purpose of multi-tasking. The chassis 100 of this embodiment is applicable to a server, and the central processing unit (CPU) and the graphics processing unit (GPU) are integrated into the chassis 100.

Referring to FIG. 1A to FIG. 1C, the chassis 100 of the disclosure includes a housing 110, a first bearing seat 120, a second bearing seat 130, and a connecting partition plate 140.

The housing 110 has a base plate 111, two lateral plates 112, and an upper cover plate 113 to form an accommodating space AS. The first bearing seat 120 is movably disposed in the accommodating space AS. The second bearing seat 130 is movably disposed in the accommodating space AS and is adjacent to the first bearing seat 120. The connecting partition plate 140 is disposed between the first bearing seat 120 and the second bearing seat 130 to connect the first bearing seat 120 and the second bearing seat 130 as one.

Referring to FIG. 1A and FIG. 1B, the first bearing seat 120 and the second bearing seat 130 are adapted to synchronously move relative to the housing 110 to be accommodated in the accommodating space AS (as shown in FIG. 1A) or extend outside the accommodating space AS (as shown in FIG. 1B). The first bearing seat 120 and the second bearing seat 130 both adopt a U-shaped structure.

Referring to FIG. 1C and FIG. 1D, the connecting partition plate 140 has a connecting plate 141, multiple engaging pillars 142, and multiple screwing members 143. The connecting partition plate 141 is located between the first bearing seat 120 and the second bearing seat 130 and is in contact with the first bearing seat 120 and the second bearing seat 130. The engaging pillars 142 are disposed on a lateral surface of the connecting plate 141 facing the second bearing seat 130, and the engaging pillars 142 are engaged to the second bearing seat 130. The screwing members 143 pass through the first bearing seat 120 and the connecting plate 141 and are screwed to a corresponding engaging pillar 142.

Specifically, the connecting partition plate 140 combines the first bearing seat 120 and the second bearing seat 130 through the engaging pillars 142 and the screwing members 143, thereby integrating the central processing unit (CPU) and the graphics processing unit (GPU) in the same node.

Referring to FIG. 1B and FIG. 1C, the first bearing seat 120 has a first hole H1 and the second bearing seat 130 has a second hole H2. The first hole H1 is adjacent to the second hole H2 and the first hole H1 and the second hole H2 are connected to each other. The first hole H1 and the second hole H2 are adapted for placing a cable 400. In addition, the lengths of the first hole H1 and the second hole H2 are adjusted according to requirements.

Referring to FIG. 1A and FIG. 1B, the chassis 100 includes multiple dissipation plates 150, includes pull rings 160, and two screwing plates 170.

The displacement plates 150 are respectively disposed on bottom surfaces of the first bearing seat 120 and the second bearing seat 130 and closely attached to an opening of the housing 110. Each of the displacement plates 150 has multiple displacement holes 151 connected to the accommodating space AS, which are used for air circulation. The pull rings 160 are respectively disposed on outer edges of the first bearing seat 120 and the second bearing seat 130 and extend outside the housing 110. Each of the pull rings 160 is used for pulling the first bearing seat 120 and the second bearing seat 130 out of the housing 110 by external force. The two screwing plates 170 are respectively disposed on the two lateral plates 112 of the housing 110, and each of the screwing plates 170 is adapted to be combined with bolts, thereby being fixed in the housing for accommodating the server.

Referring to FIG. 1B and FIG. 1C, a first calculation module 200, a second calculation module 300, and a cable 400 are further included. The first calculation module 200 and the second calculation module 300 are respectively disposed in the first bearing seat 120 and the second bearing seat 130. The first calculation module 200 includes a circuit board 210 and multiple central processing units 220. The circuit board 210 is fixedly disposed in the first bearing seat 120. The central processing units 220 are coupled circuit board 210. The second calculation module 300 includes multiple graphics processing units 310 fixedly disposed in the second bearing seat 130. The cable 400 passes through the first hole H1 of the first bearing seat 120 and the second hole H2 of the second bearing seat 130. Moreover, the cable 400 is respectively coupled to the first calculation module 200 and the second calculation module 300, so the circuit board 210 may transmit power and control signals to the second calculation module 300.

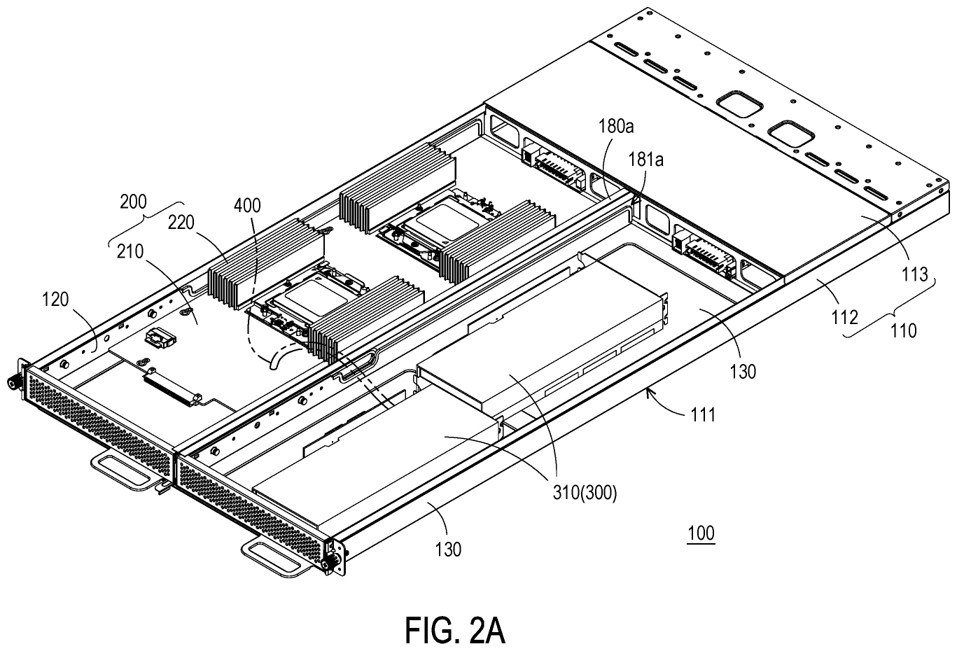

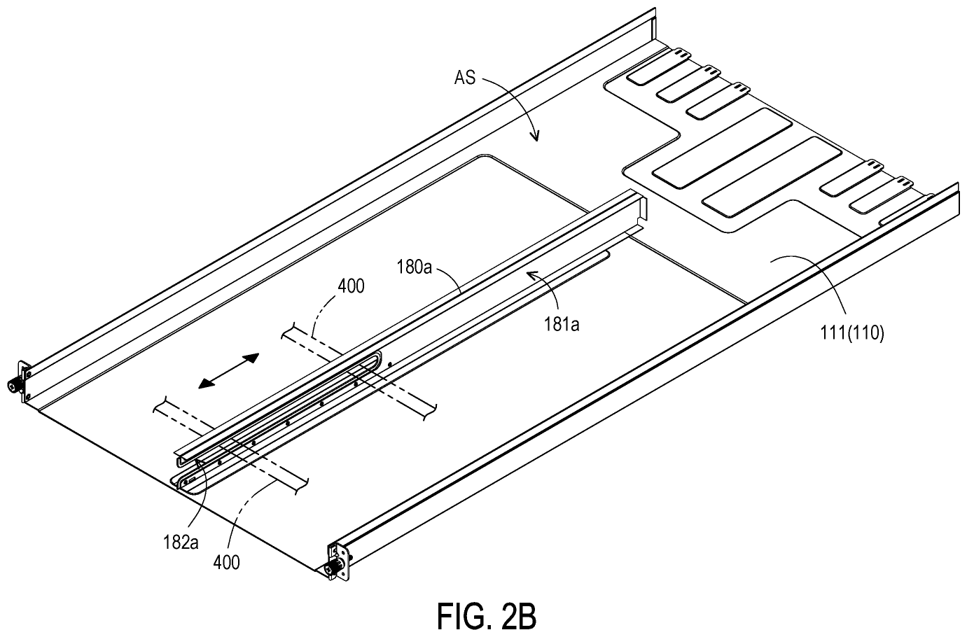

FIG. 2A is a perspective schematic view of a chassis using a limiting stand according another embodiment of the disclosure. FIG. 2B is a perspective schematic view of the limiting stand and part of the housing in FIG. 2A.

Referring to FIG. 2A and FIG. 2B, the chassis 100 of this embodiment includes a limiting stand 180a. The limiting stand 180a is fixedly disposed on the central region of the base plate 111, which divides the accommodating space AS of the housing 110 into two spaces of the same volume adapted for accommodating the first bearing seat 120 and the second bearing seat 130. Further, the limiting stand 180a has two sliding slots 181a in which the first bearing seat 120 and the second bearing seat 130 are respectively disposed. Thus, the first bearing seat 120 and the second bearing seat 130 are adapted to move linearly along the two sliding slots 181a to be accommodated in the housing 110 or extend outside the housing 110. The guiding function of the limiting stand 180a improves the fluency when the first bearing seat 120 and the second bearing seat 130 move relative to the housing 110.

Referring to FIG. 2A and FIG. 2B, the limiting stand 180a has a guiding hole 182a connected to the two sliding slots 181a, and the cable 400 passes through the guiding hole 182a movably. Specifically, the cable 400 passes through the first bearing seat 120 and the second bearing seat 130 through the guiding hole 182a and is respectively coupled to the first calculation module 200 and the second calculation module 300.

Specifically, the guiding hole 182a adopts a U-shaped appearance, so that the cable 400 coupled to the first calculation module 200 and the second calculation module 300 may only slide in the guiding hole 182a when moving without contacting the housing 110. In addition, the limiting stand 180a abuts against the base plate 111 and the upper cover plate 113 of the housing 110, thereby enhancing the structural strength of the housing 110.

In addition, the limiting stand may also be fixedly disposed on the non-central region of the base plate, which divides the accommodation space of the housing into two spaces of different volumes adapted for accommodating bearing seats of different sizes.

To sum up, the chassis of the disclosure has a first bearing seat and a second bearing seat, which are adapted for installing multiple computing processing elements. The computing elements are connected to each other through cables. The first bearing seat and the second bearing seat are connected as one through the connecting partition plate, so that the user may pull out the first bearing seat and the second bearing seat from the housing synchronously to facilitate maintenance, repair, or update of the part Compared with the existing multi-node chassis, which requires pulling out different bearing seats separately and causing cables to pull against each other, the chassis of the disclosure may avoid damage caused by cables pulling against each other when pulling them out as the first bearing seat and the second bearing seat move synchronously.

What is claimed is:

1. A chassis, comprising:
a housing having an accommodating space;
a first bearing seat movably disposed in the accommodating space;
a second bearing seat movably disposed in the accommodating space and adjacent to the first bearing seat; and
a connecting partition plate disposed between the first bearing seat and the second bearing seat to fixedly connect the first bearing seat and the second bearing seat,
wherein the first bearing seat and the second bearing seat are adapted to synchronously move relative to the housing to be accommodated in the accommodating space or extend outside the accommodating space.

2. The chassis according to claim 1, wherein the connecting partition plate has a connecting plate, a plurality of engaging pillars, and a plurality of screwing members, the connecting plate is located between the first bearing seat and the second bearing seat, the engaging pillars are disposed on a lateral surface of the connecting plate and engaged to the second bearing seat, the screwing members pass through the first bearing seat and the connecting plate and are screwed to a corresponding engaging pillar.

3. The chassis according to claim 1, wherein the first bearing seat has a first hole, the second bearing seat has a second hole, and the first hole is adjacent to the second hole.

4. The chassis according to claim 1, further comprising a plurality of dissipation plates respectively disposed on bottom surfaces of the first bearing seat and the second bearing seat and closely attached to an opening of the housing.

5. The chassis according to claim 1, further comprising a plurality of pull rings respectively disposed on outer edges of the first bearing seat and the second bearing seat and extending outside the housing.

6. The chassis according to claim 1, wherein the chassis has two screwing plates disposed on opposite sides of the chassis.

7. A chassis, comprising:
a housing having an accommodating space;
a first bearing seat movably disposed in the accommodating space;
a second bearing seat movably disposed in the accommodating space and connected to the first bearing seat; and
a limiting stand fixedly disposed in the housing and having two sliding slots in which the first bearing seat and the second bearing seat are respectively disposed,
wherein the first bearing seat and the second bearing seat are adapted to move linearly along the two sliding slots to be accommodated in the accommodating space or extend outside the accommodating space.

8. The chassis according to claim 7, wherein the limiting stand has a guiding hole connecting the two sliding slots.

9. The chassis according to claim 8, further comprising a first calculation module and a second calculation module respectively disposed in the first bearing seat and the second bearing seat.

10. The chassis according to claim 9, further comprising a cable passing through the first bearing seat and the second bearing seat through the guiding hole and respectively coupled to the first calculation module and the second calculation module.

11. The chassis according to claim 7, wherein the chassis has two screwing plates disposed on opposite sides of the chassis.
